(19) United States
(12) Patent Application Publication
(10) Pub. No.: US 2020/0258818 A1
(43) Pub. Date: Aug. 13, 2020

(54) ASSEMBLY COMPRISING A VERTICAL POWER COMPONENT ASSEMBLED ON A METAL CONNECTION PLATE

(71) Applicant: STMicroelectronics (Tours) SAS, Tours (FR)

(72) Inventors: Samuel MENARD, Chauray (FR); Laurent BARREAU, Joue Les Tours (FR)

(73) Assignee: STMicroelectronics (Tours) SAS, Tours (FR)

(21) Appl. No.: 16/785,956

(22) Filed: Feb. 10, 2020

(30) Foreign Application Priority Data
Feb. 11, 2019 (FR) 1901349

(51) Int. Cl. H01L 23/492; H01L 29/747; H01L 23/00; H01L 23/14

(52) U.S. Cl. CPC H01L 23/492; H01L 29/747; H01L 24/29; H01L 23/14; H01L 2224/29084; H01L 2924/17747; H01L 2224/29166; H01L 2224/29155; H01L 2224/29144; H01L 2924/014; H01L 2224/29124

(57) ABSTRACT

A vertical power component includes a semiconductor substrate, a first electrode in contact with a lower surface of the substrate, and a second electrode in contact with an upper surface of the substrate. The vertical component is mounted to a metal connection plate via a metal spacer. The metal spacer includes a lower surface soldered to the metal connection plate and an upper surface soldered to the first electrode of the vertical power component. The metal spacer is made of a same metal as the metal connection plate. A surface are of the metal spacer mounted to the first electrode is smaller than a surface area of the first electrode.

### PRIORITY CLAIM

This application claims the priority benefit of French Application for Patent No. 1901349, filed on Feb. 11, 2019, the content of which is hereby incorporated by reference in its entirety to the maximum extent allowable by law.

### TECHNICAL FIELD

The present disclosure generally relates to the field of electronic components. It more particularly aims at an assembly comprising a vertical power component assembled on a metal connection plate.

### BACKGROUND

U.S. Pat. No. 8,901,601 (incorporated by reference) teaches an assembly comprising a vertical power component comprising a silicon substrate, a lower main electrode in contact with a lower surface of the substrate, and an upper main electrode in contact with an upper surface of the substrate, the component being assembled on a metal connection plate so that its lower electrode is electrically connected to the metal connection plate.

To avoid wickings on the lateral surfaces of the component and to decrease the intensity of the electric field to which an insulating layer coating a peripheral portion of the lower surface of the substrate is submitted, a conductive pedestal having a smaller surface area than the component is provided between the lower electrode of the component and the metal connection plate.

Conventionally, in such assemblies, the pedestal is formed by drawing of the metal connection plate or also by etching of a portion of the thickness of the metal connection plate in a peripheral region of the plate. In other words, the pedestal and the metal connection plate form one piece (monoblock), the lower electrode of the component being soldered to the lower surface of the pedestal.

There is a need for an assembly comprising a vertical power component assembled on a metal connection plate, this assembly overcoming all or part of the disadvantages of known assemblies.

### SUMMARY

An embodiment provides an assembly comprising: a vertical power component comprising a semiconductor substrate, a first electrode in contact with a lower surface of the substrate, and a second electrode in contact with an upper surface of the substrate; a metal connection plate arranged on the lower surface side of the substrate; and a metal spacer comprising a lower surface soldered to the metal connection plate and an upper surface soldered to the first electrode of the vertical power component, the metal spacer being made of the same metal as the metal connection plate.

According to an embodiment, the metal spacer and the metal connection plate are made of copper.

According to an embodiment, a solder layer made of a material comprising tin, lead, and/or silver forms an interface between the lower surface off the metal spacer and the metal connection plate.

According to an embodiment, the height of the metal spacer is greater than 400 μm.

According to an embodiment, the vertical power component is bidirectional for voltage.

According to an embodiment, the vertical power component further comprises a gate electrode in contact with the upper surface of the substrate.

According to an embodiment, the vertical power component is a thyristor or a triac.

According to an embodiment, the surface area of the first electrode is smaller than the area of the lower surface of the substrate, a peripheral portion of the lower surface of the substrate which is not coated with the first electrode being coated with an insulating layer.

According to an embodiment, the insulating layer comprises silicon oxide and/or glass.

According to an embodiment, the surface area of the metal connection plate is greater than the surface area of the first electrode and the surface area of the metal spacer is smaller than or equal to the surface area of the first electrode.

### BRIEF DESCRIPTION OF THE DRAWINGS

The foregoing and other features and advantages will be discussed in detail in the following non-limiting description of specific embodiments in connection with the accompanying drawings, wherein:

FIG. 1 is a cross-section view schematically and partially illustrating an embodiment of an assembly comprising a vertical power component assembled on a metal connection plate; and

FIG. 2 is a cross-section view schematically and partially illustrating another embodiment of an assembly comprising a vertical power component assembled on a metal connection plate.

### DETAILED DESCRIPTION

The same elements have been designated with the same reference numerals in the different drawings. In particular, the structural and/or functional elements common to the different embodiments may be designated with the same reference numerals and may have identical structural, dimensional, and material properties.

For clarity, only those steps and elements which are useful to the understanding of the described embodiments have been shown and are detailed. In particular, the forming of the vertical power components of the described assemblies has not been detailed, the described embodiments being compatible with usual vertical power component manufacturing methods, or being within the abilities of those skilled in the art based on the indications of the present disclosure. Further, the possible applications of the described assemblies have not been detailed, the described embodiments being compatible with all or most of known uses of assemblies comprising a vertical power component assembled on a metal connection plate.

Throughout the present disclosure, the term “connected” is used to designate a direct electrical connection between circuit elements with no intermediate elements other than conductors, whereas the term “coupled” is used to designate an electrical connection between circuit elements that may be direct, or may be via one or more intermediate elements.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, “lateral”, etc., unless otherwise specified, it is referred to the orientation of the drawings, it being understood that, in practice, the described assemblies may be oriented differently.

The terms “about”, “substantially”, and “approximately” are used herein to designate a tolerance of plus or minus 10%, preferably of plus or minus 5%, of the value in question.

Vertical power component here means a component comprising a semiconductor substrate, for example, made of silicon, and first and second main electrodes respectively coating a lower surface and an upper surface of the substrate, the component configured, in the non-conductive state, to withstand between its first and second main electrodes a relatively high voltage, for example, a voltage greater than 500 volts and, in the conductive state, to conduct between its first and second main electrodes a high current, for example, a current of at least 5 amperes.

Although applicable to vertical power components which are unidirectional for voltage, the described embodiments are particularly advantageous for vertical power components which are bidirectional for voltage, that is, capable, in the non-conductive state, of withstanding relatively high positive and negative voltages, for example, voltages higher than 500 volts in absolute value.

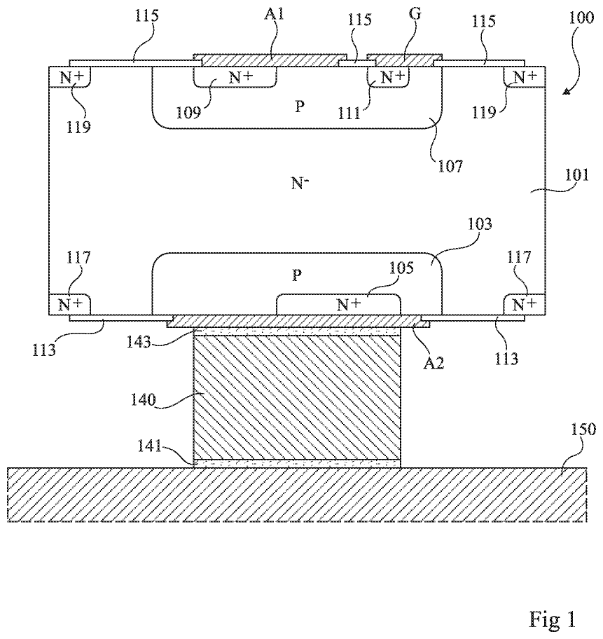

FIG. 1 is a cross-section view schematically and partially illustrating an embodiment of an assembly comprising a vertical power component 100 on a metal connection plate 150.

In the example of FIG. 1, component 100 is a triac formed in so-called “planar” technology.

Triac 100 comprises an N-type doped silicon substrate 101. The doping level of substrate 101 may be relatively low (N−), for example, in the range from 10¹³ to 10¹⁵ atoms/cm³. The thickness of substrate 101 is, for example, in the range from 100 to 500 μm, for example, in the order of 200 μm. In top view (not shown), substrate 101 has, for example, a square or rectangular general shape. The surface area of the substrate, in top view, may be relatively large, for example, greater than 1 mm², for example, in the range from 1 to 25 mm².

On the lower surface side of substrate 101, triac 100 comprises a local P-type doped well 103 (P), extending opposite a central portion of the component. Laterally, well 103 extends over almost the entire lower surface of substrate 101, except at the periphery thereof. As an example, well 103 extends laterally over than more than 60 percent and preferably over more than 80 percent of the surface area of the lower surface of the substrate. Vertically, well 103 extends from the lower surface of substrate 101, all the way to an intermediate level of substrate 101. The thickness of well 103 is, for example, in the range from 10 to 30 percent of an overall thickness of substrate 101. As an example, the thickness of well 103 is in the range from 30 to 80 μm, for example, in the order of 50 μm. The doping level of well 103 is for example in the range from 10¹⁶ to 5*10¹⁹ atoms/cm³.

On the lower surface side of substrate 101, triac 100 further comprises, inside of well 103, a local N-type doped region 105. Region 105 may be relatively heavily N-type doped (N+), for example with a doping level in the range from 10¹⁹ to 10²¹ atoms/cm³, for example in the order of 10²⁰ atoms/cm³. Laterally, region 105 extends over a portion only of the surface of well 103, and does not extend all the way to the edge of well 103. As an example, region 105 extends over from 30 to 70 percent of the surface of well 105. Vertically, region 105 extends from the lower surface side of well 103 to an intermediate level of well 103. The thickness of region 105 is, for example, in the range from 20 to 50 percent of an overall thickness of well 103. As an example, the thickness of region 105 is in the range from 10 to 30 μm, for example, in the order of 20 μm.

On the upper surface side of substrate 101, triac 100 comprises a local P-type doped well 107 (P), extending opposite a central portion of the component. Laterally, well 107 extends over almost the entire upper surface of substrate 101, except at the periphery thereof. As an example, well 107 extends laterally over than more than 60 percent and preferably over more than 80 percent of the upper surface side of the substrate. Well 107 is, for example, located substantially opposite well 103. Vertically, well 107 extends from the upper surface side of substrate 101 and stops before reaching the upper surface of well 103. The thickness of well 107 is, for example, in the range from 10 to 30 percent of an overall thickness of substrate 101. As an example, the thickness of well 107 is in the range from 30 to 80 μm, for example, in the order of 50 μm. The doping level of well 107 is, for example, in the range from 10¹⁶ to 5*10¹⁹ atoms/cm³. The thickness and the doping level of well 107 are, for example, substantially identical respectively to the thickness and to the doping level of well 103.

On the upper surface side of substrate 101, triac 100 further comprises, inside of well 107, a local N-type doped region 109. Region 109 may be relatively heavily N-type doped (N+), for example with a doping level in the range from 10¹⁹ to 10²¹ atoms/cm³, for example in the order of 10²⁰ atoms/cm³. Laterally, region 109 extends over a portion only of the upper surface of well 107, and does not extend all the way to the edge of well 109. As an example, region 109 extends over from 30 to 70% of the upper surface of well 107. Region 109 is, for example, arranged in an area substantially complementary to that occupied by region 105. Vertically, region 109 extends from the upper surface of well 107 to an intermediate level of well 107. The thickness of region 109 is, for example, in the range from 20 to 50 percent of an overall thickness of well 107. As an example, the thickness of region 109 is in the range from 10 to 30 μm, for example, in the order of 20 μm. The thickness and the doping level of region 109 are, for example, substantially identical respectively to the thickness and to the doping level of region 105.

Upper well 107 further comprises a local N-type doped region 111 having a smaller extent than region 109. Laterally, region 111 does not extend all the way to the edge of well 107, neither does it extend all the way to region 109. As an example, region 111 extends over less than 10% of the surface of well 107. The thickness and the doping level of region 111 are, for example, substantially identical respectively to the thickness and to the doping level of region 105.

Triac 100 of FIG. 1 further comprises, on the lower surface side of substrate 101, a first main metal electrode or conduction electrode A2, in contact with the lower surface of well 103 and of region 105. As an example, electrode A2 comprises a stack of metal layers comprising, in the following order from the lower surface of the substrate, an aluminum layer, a titanium layer, a nickel layer, and a gold layer. In a variant, electrode A2 comprises only a nickel layer and a gold layer. Laterally, electrode A2 does not extend beyond the edges of well 103. Thus, the surface area of electrode A2 is smaller than or equal to the surface area of well 103.

Outside of well 103, at the periphery of the component, the lower surface of substrate 101 is coated with an insulating passivation layer 113, for example, made of silicon oxide or of glass.

Triac 100 further comprises, on the upper surface side of substrate 101, a second main metal electrode or conduction electrode A1, in contact with the upper surface of well 107 and of region 109. Triac 100 further comprises, on its upper surface side, a gate electrode G in contact with the upper surface of region 111. Gate electrode G may further be in contact with a portion of the upper surface of well 107. Electrodes A1 and G are for example made of aluminum, or of an alloy comprising nickel and gold.

On its upper surface side, triac 100 comprises an insulating passivation layer 115, for example, made of silicon oxide or of glass, coating the portions of the upper surface of the substrate which are not coated with electrodes A1 and G.

The thickness of the upper and lower insulating passivation layers 113 and 115 may be relatively small, for example, in the range from 2 to 15 μm.

Whatever the polarity of the voltage applied between electrodes A1 and A2, if an appropriate gate control signal is supplied on electrode G, the component turns on. The conduction is achieved from electrode A2 to electrode A1 by a vertical thyristor comprising regions 103, 101, 107, and 109 (P-N-P-N) or from electrode A1 to electrode A2 by a vertical thyristor comprising regions 107, 101, 103, and 105 (P-N-P-N). The thickness and the doping level of substrate 101 are calculated so that the triac, in the non-conductive state, can withstand high voltages, for example, voltages higher than 500 volts in absolute value.

To avoid for breakdowns to occur at the component edges, a relatively large distance, for example, in the range from 50 to 200 μm, for example, in the order of 100 μm, may be provided between the peripheral limit of P-type wells 103 and 107 and the edge of the component. In this example, two N-type doped channel stop rings 117 and 119 extend respectively at the lower periphery and at the upper periphery of substrate 101, at a distance from the edges of wells 103 and 107, contributing to avoiding breakdowns at the component edges. The doping level of channel stop rings 117 and 119 may be relatively high (N+). As an example, the thickness and the doping level of channel stop rings 117 and 119 may be substantially identical respectively to the thickness and to the doping level of regions 105, 109, and 111.

In the example of FIG. 1, lower electrode A2 of triac 100 is soldered to metal plate 150 via a metal spacer or pedestal 140. Metal plate 150 may be a metal plate of a heat sink, a connection plate of a printed circuit board or of a package, etc.

The surface of metal plate 150 extends laterally beyond the edges of well 103. In other words, the surface area of metal plate 150 is greater than or equal to the area of the lower surface of well 103. As an example, the surface area of metal plate 150 is greater than or equal to the area of the lower surface of triac 100.

Spacer 140, for example, has a generally parallelepipedal or cylindrical shape. Laterally, spacer 140 does not extend beyond the edges of electrode A2. In other words, spacer 140 has a surface area smaller than or equal to the area of the lower surface of electrode A2. In the shown example, spacer 140 has a surface area strictly smaller than the surface area of electrode A2.

Spacer 140 is made of the same metal as metal plate 150, preferably, copper.

Spacer 140 enables to avoid wickings on the lateral surfaces of triac 100, which might otherwise electrically couple electrode A2 to substrate 101 and thus short-circuit the PN junction formed between well 103 and substrate 101. Indeed, in “planar” technology, as appears in FIG. 1, the lateral surfaces of substrate 101 are not insulated.

Spacer 140 further enables to decrease the intensity of the electric field to which insulating layer 113 is submitted due to the strong potential difference between substrate 101 and metal plate 150. This enables to limit risks of component breakdown and to decrease off-state leakage currents. Further, this enables to symmetrize the operation of the component between its upper portion and its lower portion, which constitutes an important difference compared with known voltage bidirectional components in planar technology.

According to an aspect of an embodiment, metal spacer 140 is an added part, soldered by its lower portion to the upper surface of metal plate 150, rather than a part forming one piece with metal plate 150, obtained by drawing or etching of metal plate 150.

Thus, in the assembly of FIG. 1, a layer 141 of a welding or solder material, for example, a material made up of tin, of lead, and/or of silver, forms an interface between the lower surface of spacer 140 and the upper surface of metal plate 150.

A solder coat 143, for example, made of the same material as layer 141, forms an interface between the upper surface of spacer 140 and the lower surface of electrode A2.

An advantage of the embodiment described in relation with FIG. 1 is that it is easier to affix a spacer placed by soldering on the lower metal connection plate than to form a pedestal forming one piece with the lower metal plate, by drawing or etching of the metal plate.

Preferably, spacer 140 has a relatively large height, for example, greater than 400 μm, which cannot currently be achieved by conventional drawing or etching methods, given the relatively small usual thicknesses of the lower metal connection plate. This enables to significantly improve the voltage behavior of the component.

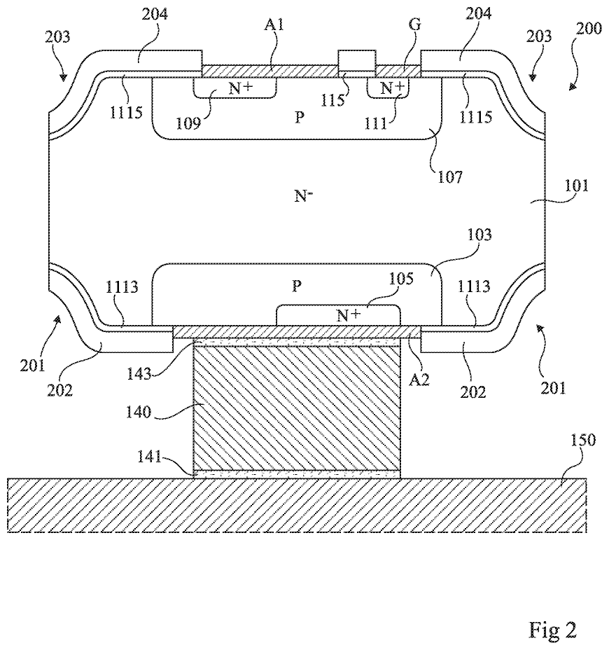

FIG. 2 is a cross-section view schematically and partially illustrating another embodiment of an assembly comprising a vertical power component assembled on a metal connection plate.

The assembly of FIG. 2 differs from the assembly of FIG. 1 mainly in that, in the assembly of FIG. 2, triac 100 is replaced with a triac 200. Triac 200 of FIG. 2 differs from triac 100 mainly by the structure of its periphery.

Triac 200 of FIG. 2 comprises, at the periphery of each of the lower and upper surfaces of substrate 101, a lateral trench, respectively 201 and 203, at least partially filled with a passivation layer, respectively 202 and 204, for example, made of glass.

Laterally, the peripheral edge of the P-type wells 103 and 107 stops before trenches 201 and 203, respectively. On the lower surface side of the component, the passivation layer 202 extends under the peripheral substrate region extending between well 103 and trench 201. In this example, a semiresistive layer 1113, for example, made of polycrystalline silicon doped with oxygen (SIPOS), extends between the lower surface of the substrate and the passivation layer 202. On the upper surface side of the component, the passivation layer 204 extends on the peripheral substrate region extending between well 107 and trench 203. In this example, a semiresistive layer 1115, for example, made of the same material as layer 1113, extends between the upper surface of the substrate and the passivation layer 204.

Similarly to what has been described in relation with FIG. 1, spacer 140 further enables to decrease the intensity of the electric field to which insulating layer is submitted due to the strong potential difference between substrate 101 and metal plate 150. This enables to limit risks of component breakdown and to decrease off-state leakage currents. Further, this enables to symmetrize the operation of the component between its upper portion and its lower portion.

Various embodiments and variations have been described. Those skilled in the art will understand that certain features of these various embodiments and variations may be combined, and other variations will occur to those skilled in the art. In particular, the described embodiments are not limited to the examples of numerical values and of materials mentioned in the disclosure.

Further, the embodiments are not limited to the examples of vertical power components described in relation with FIGS. 1 and 2. More generally, the above-described assembly by means of an added metal spacer, soldered to a metal connection plate, may be applied to any vertical power component and especially, particularly advantageously, to any vertical power component bidirectional for voltage (triac, thyristors, Shockley diode, etc.).

Further, it should be noted that in the examples described in relation with FIGS. 1 and 2, all the conductivity types of the semiconductor regions may be inverted.

1. An assembly, comprising:
a vertical power component comprising a semiconductor substrate doped with a first conductivity type and having a lower surface, a region within the semiconductor substrate at the lower surface that is doped with a second conductivity type, a first electrode in contact with said region at the lower surface, and a second electrode in contact with an upper surface of the semiconductor substrate;
a metal connection plate; and
a metal spacer comprising a lower surface soldered to the metal connection plate and an upper surface soldered to a lower surface of the first electrode of the vertical power component, the metal spacer being made of a same metal as the metal connection plate;
wherein a surface area of the upper surface of the metal spacer is smaller than a surface area of the lower surface of the first electrode and smaller than a surface area of said region at the lower surface of the semiconductor substrate.

2. The assembly of claim 1, wherein the same metal of the metal spacer and the metal connection plate is copper.

3. The assembly of claim 1, wherein a solder layer made of a material comprising one or more of tin, lead, and silver forms an interface between the lower surface of the metal spacer and the metal connection plate.

4. The assembly of claim 1, wherein the metal spacer has a height for spacing the vertical power component from the metal connection plate by a distance that is greater than 400 μm.

5. The assembly of claim 1, wherein the vertical power component is bidirectional for voltage.

6. The assembly of claim 1, wherein the vertical power component further comprises a gate electrode in contact with the upper surface of the semiconductor substrate.

7. The assembly of claim 1, wherein the vertical power component is a thyristor or a triac.

8. The assembly of claim 1, wherein the surface area of the first electrode is smaller than a surface area of the lower surface of the semiconductor substrate, and further comprising an insulating layer which covers a peripheral portion of the lower surface of the semiconductor substrate that is not coated with the first electrode.

9. The assembly of claim 8, wherein the insulating layer comprises silicon oxide and/or glass.

10. The assembly of claim 1, wherein a surface area of the metal connection plate mounted to the metal spacer is greater than the surface area of the lower surface of the first electrode.

11. The assembly of claim 1, where the vertical power component further comprises a further region within said region at the lower surface, the further region doped with the first conductivity type, and wherein the first electrode is in contact with said further region at the lower surface of the semiconductor substrate.

12. An assembly, comprising:
a vertical power component comprising a semiconductor substrate doped with a first dopant type, a first electrode in contact with a lower surface of the semiconductor substrate, and a second electrode in contact with an upper surface of the semiconductor substrate; and
a metal spacer comprising an upper surface soldered to a lower surface of the first electrode of the vertical power component;
wherein a surface area of an upper surface of the first electrode is smaller than a surface area of a region at the lower surface of the semiconductor substrate that is doped with a second dopant type; and
wherein a surface area of the upper surface of the metal spacer is smaller than a surface area of the lower surface of the first electrode.

13. The assembly of claim 12, further comprising a metal connection plate, wherein a lower surface of the metal spacer is soldered to the metal connection plate, and wherein the metal spacer is made of a same metal as the metal connection plate.

14. The assembly of claim 13, wherein the same metal of the metal spacer and the metal connection plate is copper.

15. The assembly of claim 12, wherein a height of the metal spacer is greater than 400 μm.

16. The assembly of claim 12, wherein the vertical power component is bidirectional for voltage.

17. The assembly of claim 12, wherein the vertical power component further comprises a gate electrode in contact with the upper surface of the substrate.

18. The assembly of claim 12, wherein the vertical power component is a thyristor or a triac.

19. The assembly of claim 12, further comprising an insulating layer which covers a peripheral portion of the lower surface of the semiconductor substrate that is not coated with the first electrode.

20. The assembly of claim 19, wherein the insulating layer is made of a material comprising one or more of silicon oxide and glass.
